(19) United States
(12) Patent Application Publication
(10) Pub. No.: US 2026/0165034 A1
(43) Pub. Date: Jun. 11, 2026

(54) SUPERCONDUCTING QUANTUM CHIP PREPARATION METHOD AND SUPERCONDUCTING QUANTUM CHIP

(71) Applicant: YANGTZE DELTA INDUSTRIAL INNOVATION CENTER OF QUANTUM SCIENCE AND TECHNOLOGY, Suzhou (CN)

(72) Inventors: Weiwen ZHENG, Suzhou (CN); Hui YANG, Suzhou (CN); Yang REN, Suzhou (CN); Zi LIU, Suzhou (CN)

(21) Appl. No.: 18/979,704

(22) Filed: Dec. 13, 2024

(30) Foreign Application Priority Data
Jan. 5, 2023 (CN) 202310011440.6

(51) Int. Cl. H10N 60/01; H10N 60/12

(52) U.S. Cl. CPC H10N 60/0912; H10N 60/0884; H10N 60/12

(57) ABSTRACT

The present application discloses a superconducting quantum chip preparation method and a superconducting quantum chip, and is applied to the technical field of quantum chips. The method includes the steps: arranging a separation layer on the surface of a first substrate; arranging an air bridge on the surface of the separation layer; the bridge surface of the air bridge is attached to the separation layer, and the bridge pier of the air bridge extends from the separation layer to the direction opposite to one side of the first substrate; electrically connecting the air bridge and the circuit device which are aligned with each other; after the air bridge and the circuit device are electrically connected with each other, separating the first substrate and the air bridge from each other through the separation layer, such that the superconducting quantum chip is manufactured.

### CROSS-REFERENCE TO RELATED APPLICATIONS

The present application is a continuation of International Application No. PCT/CN 2024/070272, with an international filing date of Jan. 3, 2024, which is based upon and claims priority to Chinese Patent Application No. 202310011440.6, filed on Jan. 5, 2023, the entire contents of all of which are incorporated herein by reference.

### TECHNICAL FIELD

The present disclosure relates to a technical field of quantum chip, particularly to superconducting quantum chip preparation method and superconducting quantum chip.

### BACKGROUND

Superconducting quantum has been developed rapidly in recent twenty years, especially in quantum chips, providing the possibility of realizing fault-tolerant quantum computing. To realize possible quantum computing, a minimum of 1,000 quantum bits are required. At present, the superconducting quantum chip uses a coplanar waveguide structure and utilizes a microwave measurement and control technology to read and control bit information. Due to the multi-bit chip layout design and the actual processing and preparation, the coplanar waveguide structure will have obvious parasitic mode, which will affect the signal measurement and control, and the simultaneous control of multi-bits will also bring obvious mutual crosstalk. In order to eliminate or reduce the effects of these parasitics and crosstalk, an air bridge is commonly used to electrically connect the ground planes that are split by CPW (Coplanar Waveguide Structure).

Currently, after a large structure and a Josephson junction are prepared, an air bridge is basically prepared on the same plane using photoresist thermal reflow or other materials as a sacrificial layer in combination with photoetching, film coating and etching processes. However, in either solution, since the process is performed on the same plane, the subsequent processes will have impact and risk on the previous large structure and Josephson junction.

However, in the prior art, there are risks of residual contamination and impact on the performance of the original device if an air bridge is prepared by processes of photolithography, coating, and etching after a coplanar waveguide structure and Josephson junction are prepared. For example, high temperature processes such as photolithography baking and photoresist reflow can significantly affect the characteristics of Josephson junction, thereby changing the overall performance of a chip. If an air bridge is processed before the preparation of Josephson junction, the presence of the air bridge will significantly interfere with the preparation of Josephson junction, limiting the overall processing of the device. Accordingly, how to avoid the negative impact caused by assembling of the air bridge is an urgent problem to be solved by those skilled in the art.

### SUMMARY

The present disclosure aims at providing a superconducting quantum chip preparation method which can avoid the negative impact caused by assembling of the air bridge. The present disclosure further aims at providing a superconducting quantum chip, which can avoid the negative impact caused by assembling of the air bridge.

To solve the above technical problem, the present disclosure provides a superconducting quantum chip preparation method, comprising:
arranging a separation layer on a surface of a first substrate;
arranging an air bridge on a surface of the separation layer; a bridge surface of the air bridge is attached to the separation layer, and a bridge pier of the air bridge extends from the separation layer to the direction opposite to one side of the first substrate;
aligning the first substrate and the second substrate with each other; one side of the first substrate facing the second substrate is provided with the air bridge, and one side of the second substrate facing the first substrate is provided with a circuit device;
electrically connecting the air bridge and the circuit device which are aligned with each other; and
separating the first substrate and the air bridge from each other through the separation layer after the air bridge and the circuit device are electrically connected with each other, such that the superconducting quantum chip is manufactured.

Alternatively, the step of electrically connecting the air bridge and the circuit device which are aligned with each other comprises:
welding the air bridge and the circuit device which are aligned with each other based on a flip-chip bonding equipment.

Alternatively, the step of arranging an air bridge on a surface of the separation layer comprises:
arranging a superconducting layer in a preset area on the surface of the separation layer;
shielding an area corresponding to the bridge pier in the superconducting layer through a first mask, and exposing an area corresponding to the bridge surface in the superconducting layer; and
etching an area corresponding to the bridge surface in the superconducting layer through the first mask to form the air bridge.

Alternatively, the step of shielding an area corresponding to the bridge pier in the superconducting layer through a first mask, and exposing an area corresponding to the bridge surface in the superconducting layer comprises:
arranging a photoresist on the surface of the superconducting layer, and photoetching in an area corresponding to the bridge surface to form the first mask.

Alternatively, the step of arranging a superconducting layer in a preset area on the surface of the separation layer comprises:
arranging a photoresist on the surface of the separation layer, and photoetching in a corresponding preset area to form a superconducting layer mask exposing the preset area; and
stripping the superconducting layer mask after plating the superconducting material through the superconducting layer mask, to form a superconducting layer in the preset area.

Alternatively, the step of arranging an air bridge on a surface of the separation layer comprises:
arranging a superconducting layer in a preset area on the surface of the separation layer;
shielding an area corresponding to the bridge surface in the superconducting layer through a second mask, and exposing an area corresponding to the bridge pier in the superconducting layer; and
arranging a superconducting material in an area corresponding to the bridge pier in the superconducting layer through the second mask to form the air bridge.

Alternatively, the step of shielding an area corresponding to the bridge surface in the superconducting layer through a second mask, and exposing an area corresponding to the bridge pier in the superconducting layer comprises:
arranging a photoresist on the surface of the superconducting layer, and photoetching in an area corresponding to the bridge pier to form the second mask.

Alternatively, the step of arranging a superconducting material in an area corresponding to the bridge pier in the superconducting layer through the second mask to form the air bridge comprises:
evaporating a superconducting material through the second mask based on an evaporation process; and
stripping the second mask to form the air bridge.

Alternatively, the separation layer is an electron beam photoresist layer;
the step of separating the first substrate and the air bridge from each other through the separation layer comprises:
immersing the electrically connected sample into a dissolving solution to dissolve the separation layer to separate the first substrate and the air bridge.

The present disclosure further provides a superconducting quantum chip comprising a superconducting quantum chip prepared by a superconducting quantum chip preparation method according to any one of the above steps.

The superconducting quantum chip preparation method provided by the present disclosure comprises: arranging a separation layer on a surface of a first substrate; arranging an air bridge on a surface of the separation layer; a bridge surface of the air bridge is attached to the separation layer, and a bridge pier of the air bridge extends from the separation layer to the direction opposite to one side of the first substrate; aligning the first substrate and the second substrate with each other; one side of the first substrate facing the second substrate is provided with the air bridge, and one side of the second substrate facing the first substrate is provided with a circuit device; electrically connecting the air bridge and the circuit device which are aligned with each other; and separating the first substrate and the air bridge from each other through the separation layer after the air bridge and the circuit device are electrically connected with each other, such that the superconducting quantum chip is manufactured.

An air bridge is separately arranged on the surface of the first substrate, and then the air bridge is directly flip-chip welded to the surface of the second substrate through a flip-chip welding process to be connected with the circuit device, so that the preparation of the air bridge and the preparation of other circuit devices are separated from each other without interfering with each other. Finally, it only needs to connect the air bridge and the circuit device to each other by flip-chip bonding equipment, avoiding the interference caused by successively preparing the air bridge and the circuit device on the surface of the substrate, and avoiding the negative impact caused by assembling the air bridge.

The present disclosure further aims at providing a superconducting quantum chip, which can achieve the above advantageous effects, and thus it will not be described in detail herein.

### BRIEF DESCRIPTION OF THE DRAWINGS

In order to more clearly explain the technical solutions in the embodiments of the present disclosure or the prior art, drawings required in the embodiments or the prior art will be briefly described below. Obviously, the drawings in the following description are some embodiments of the present disclosure. For those skilled in the art, other drawings may be obtained from these drawings without any creative effort.

FIGS. 1 to 5 are process flow diagrams of a superconducting quantum chip preparation method according to an embodiment of the present disclosure;

FIGS. 6 to 12 are process flow diagrams of a specific superconducting quantum chip preparation method according to an embodiment of the present disclosure;

FIGS. 13 to 16 are process flow diagrams of a further specific superconducting quantum chip preparation method according to an embodiment of the present disclosure.

In the figures: 1. the first substrate, 2. separation layer, 3. air bridge, 31. a superconducting layer mask, 32. a superconducting layer, 33. the first mask, 34. the second mask, 4. the second substrate, 5. circuit device.

### DETAILED DESCRIPTION OF THE EMBODIMENTS

The core of the present disclosure is to provide a superconducting quantum chip preparation method. In the prior art, there are risks of residual contamination and impact on the performance of the original device, if an air bridge is prepared by processes of photolithography, coating, and etching after a coplanar waveguide structure and Josephson junction are prepared. For example, high temperature processes such as photolithography baking and photoresist reflow can significantly affect the characteristics of Josephson junction, thereby changing the overall performance of a chip. If an air bridge is processed before the preparation of Josephson junction, the presence of the air bridge will significantly interfere with the preparation of Josephson junction, limiting the overall processing of the device.

However, a superconducting quantum chip preparation method provided by the present disclosure comprises: arranging a separation layer on a surface of a first substrate; arranging an air bridge on a surface of the separation layer; a bridge surface of the air bridge is attached to the separation layer, and a bridge pier of the air bridge extends from the separation layer to the direction opposite to one side of the first substrate; aligning the first substrate and the second substrate with each other; one side of the first substrate facing the second substrate is provided with the air bridge, and one side of the second substrate facing the first substrate is provided with a circuit device; electrically connecting the air bridge and the circuit device which are aligned with each other; and separating the first substrate and the air bridge from each other through the separation layer after the air bridge and the circuit device are electrically connected with each other, such that the superconducting quantum chip is manufactured.

An air bridge is separately arranged on the surface of the first substrate, and then the air bridge is directly flip-chip welded to the surface of the second substrate through a flip-chip welding process to be connected with the circuit device, so that the preparation of the air bridge and the preparation of other circuit devices are separated from each other without interfering with each other. Finally, it is only necessary to connect the air bridge and the circuit device to each other by flip-chip bonding equipment, avoiding the interference caused by successively preparing the air bridge and the circuit device on the surface of the substrate, and avoiding the negative impact caused by assembling the air bridge.

In order to enable those skilled in the art to better understand the aspects of the present disclosure, the present disclosure will now be described in further detail with reference to the accompanying drawings and detailed description. Obviously, the described embodiments are part of, but not all of, the embodiments of the present disclosure. Based on the embodiments of the present disclosure, all the other embodiments obtained by those skilled in the art without paying any creative work fall within the protection scope of the present disclosure.

With reference to FIGS. 1 to 5, FIGS. 1 to 5 are process flow diagrams of a superconducting quantum chip preparation method according to an embodiment of the present disclosure.

Referring to FIG. 1, in an embodiment of the present disclosure, a superconducting quantum chip preparation method comprises:
S101: arranging a separation layer on a surface of a first substrate.

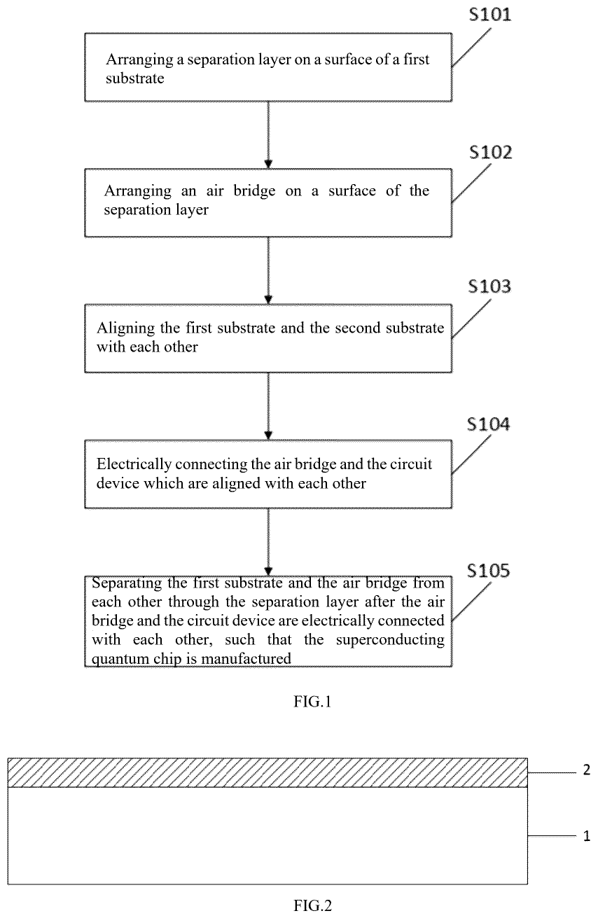

Referring to FIG. 2, the first substrate 1 is used to provide the air bridge 3 separately. The first substrate 1 needs only to be a flat sheet. In this step, a separation layer 2 is first provided on the surface of the first substrate 1 so as to finally separate the first substrate 1 and the air bridge 3 from each other.

Specifically, in the embodiment of the present disclosure, the above separation layer 2 may be an electron beam photoresist layer, that is, an electron beam photolithography is applied to the surface of the substrate to form a separation layer 2. Certainly, in the embodiment of the present disclosure, it is also possible to use other materials as the separation layer 2 as long as the air bridge 3 and the substrate can be separated from each other. The specific material of the separation layer 2 is not specifically limited in the embodiment of the present disclosure.

Before this step, it is specifically necessary to clean the first substrate 1.
S102: arranging an air bridge on a surface of the separation layer.

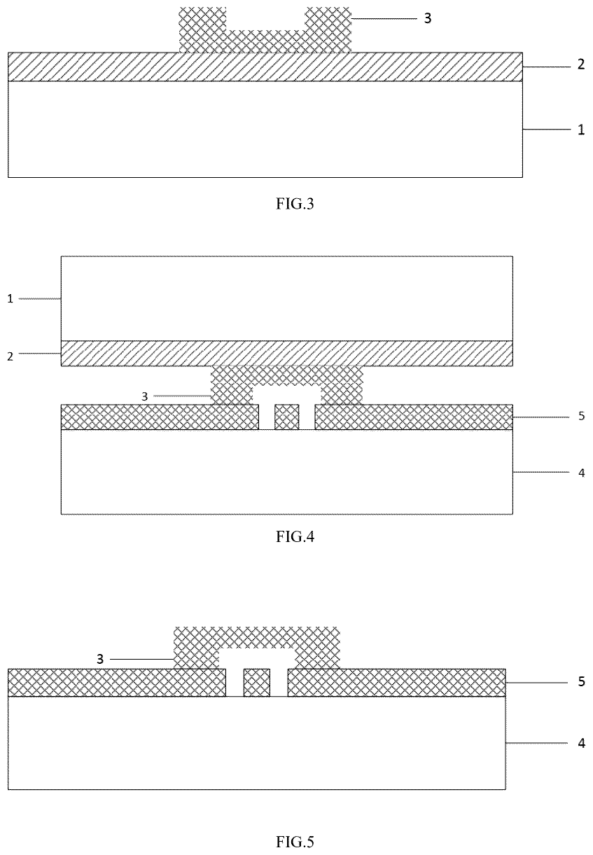

Referring to FIG. 3, in the embodiment of the present disclosure, a bridge surface of the air bridge 3 is attached to the separation layer 2, and a bridge pier of the air bridge 3 extends from the separation layer 2 to the direction opposite to one side of the first substrate 1. In this step, an air bridge 3 is arranged on the surface of the separation layer 2, and the air bridge 3 is in an inverted structure, that is, the bridge surface of the air bridge 3 is in contact with the separation layer 2, and the bridge pier extends from the separation layer 2 to the direction opposite to one side of the first substrate 1, i.e., the bridge pier extends upward from the separation layer 2, thereby forming an inverted structure of the air bridge 3, so as to connect the air bridge 3 with a quantum circuit through a flip-chip process.

The specific preparation process of the air bridge 3 will be described in detail in the following embodiments of the present disclosure and will not be described in detail herein.
S103: aligning the first substrate and the second substrate with each other.

In an embodiment of the present disclosure, one side of the first substrate 1 facing the second substrate 4 is provided with the air bridge 3, and one side of the second substrate 4 facing the first substrate 1 is provided with a circuit device 5. One side of the first substrate 1 facing the second substrate 4 is provided with the air bridge 3, and one side of the second substrate 4 facing the first substrate 1 is provided with a circuit device 5. The circuit device 5 is usually formed with a plurality of coplanar waveguide structures separated from each other, the plurality of coplanar waveguide structures form a quantum circuit, and the air bridge 3 is specifically used for connecting the adjacent coplanar waveguide structures. With regard to the specific structure of the circuit device 5, it can be set according to actual conditions, and will be not particularly limited herein.

In this step, the first substrate 1 and the second substrate 4 are aligned with each other. Specifically, the air bridge 3 and the circuit device 5 are aligned with each other, so that the air bridge 3 that is electrically connected can connect the adjacent coplanar waveguide structures.

In the embodiment of the present disclosure, the second substrate 4 may be a high-resistance silicon substrate or a sapphire substrate, and the second substrate 4 may be specifically used as a substrate of the final superconducting quantum chip.
S104: electrically connecting the air bridge and the circuit device which are aligned with each other.

Referring to FIG. 4, in this step, the air bridge 3 and the circuit device 5 are electrically connected to each other, that is, the first substrate 1 and the second substrate 4 provided with the corresponding structures are aligned and pressure-welded by a flip-chip bonding equipment, so that the air bridge 3 and the circuit device 5 are bonded to each other.

This step may specifically comprise welding the air bridge and the circuit device which are aligned with each other based on a flip-chip bonding equipment. In this step, a flip-chip bonding equipment is specifically used, and the air bridge 3 and the circuit device 5 are electrically connected to each other based on a flip-chip bonding technique. Certainly, other devices may also be used for connection in the embodiment of the present disclosure, which is not limited herein.
S105: separating the first substrate and the air bridge from each other through the separation layer after the air bridge and the circuit device are electrically connected with each other, such that the superconducting quantum chip is manufactured.

Referring to FIG. 5, in this step, after the first substrate 1 and the second substrate 4 are electrically connected to each other, a substrate and the air bridge 3 are separated from each other by the separation layer 2, thereby completing the preparation of the superconducting quantum chip. Specifically, the step may specifically include immersing the electrically connected sample into a dissolving solution to dissolve the separation layer 2, and separating the first substrate 1 and the air bridge 3. Specifically, the first substrate 1 and the air bridge 3 can be separated from each other by dissolving the separation layer 2.

When the separation layer 2 is an electron beam photoresist layer, the step may include immersing a sample formed after the air bridge 3 and the circuit device 5 are electrically connected to each other in an NMP (N-methylpyrrolidone) solution at 80° C., and soaking it to remove the electron beam photoresist, thereby separating the first substrate 1 and the air bridge 3. Certainly, according to different materials of the separation layer 2, the above dissolving solution may also be selected from the solution with other components for dissolving the separation layer 2. The specific components of the solution are not specifically limited in the embodiment of the present disclosure. After the first substrate 1 is separated, it is usually necessary to continue cleaning the remaining sample to ensure that the photoresist is removed completely. Certainly, in the embodiment of the present disclosure, the first substrate 1 and the air bridge 3 may be separated from each other by other means, such as stripping the separation layer 2.

In the superconducting quantum chip preparation method provided by the embodiments of the present disclosure, an air bridge 3 is separately arranged on the surface of the first substrate 1, and then the air bridge 3 is directly flip-chip welded to the surface of the second substrate 4 through a flip-chip welding process to be connected with the circuit device 5, so that the preparation of the air bridge 3 and the preparation of other circuit devices are separated from each other without interfering with each other. Finally, it is only necessary to connect the air bridge 3 and the circuit device 5 to each other by flip-chip bonding equipment, avoiding the interference caused by successively preparing the air bridge 3 and the circuit device 5 on the surface of the substrate, and avoiding the negative impact caused by assembling the air bridge 3.

The specific contents of a superconducting quantum chip preparation method provided by the present disclosure will be described in detail in the following embodiments of the present disclosure.

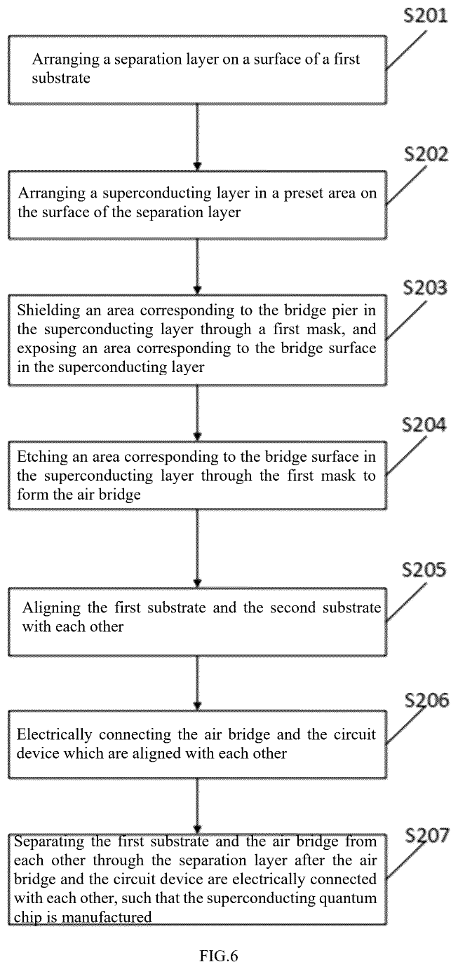

With reference to FIGS. 6 to 12, FIGS. 6 to 12 are process flow diagrams of a specific superconducting quantum chip preparation method according to an embodiment of the present disclosure.

Referring to FIG. 6, in an embodiment of the present disclosure, a superconducting quantum chip preparation method comprises:
S201: arranging a separation layer on a surface of a first substrate.

This step is basically the same as S101 in the above embodiment of the present disclosure. Please refer to the above embodiment of the present disclosure for details, and the detailed description will not be repeated herein.
S202: arranging a superconducting layer in a preset area on the surface of the separation layer.

The preset area in this step is the area where the air bridge 3 is arranged, and in this step, it is first necessary to arrange a superconducting material on the surface of the separation layer 2 corresponding to a preset area where the air bridge 3 needs to be arranged to form a superconducting layer 32, so as to form the air bridge 3 based on the arrangement of the superconducting layer 32. Generally, the superconducting layer 32 is made of a material of any of indium (In), tantalum (Ta), niobium (Nb), titanium nitride (TiN), and niobium nitride (NbN). Certainly, the specific material of the superconducting layer 32 is not specifically limited herein, depending on the specific situations.

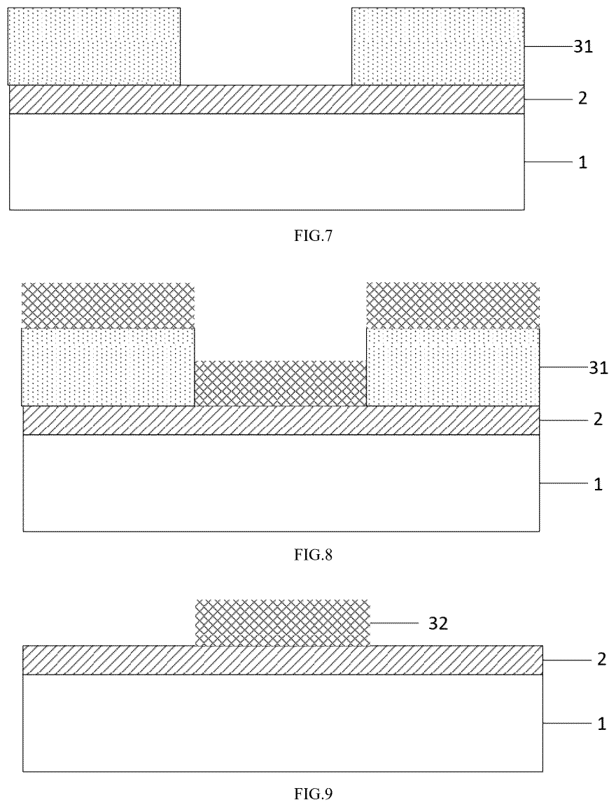

Referring to FIG. 7, FIG. 8 and FIG. 9, specifically, this step may include: arranging a photoresist on the surface of the separation layer 2, and photoetching in a corresponding preset area to form a superconducting layer mask 31 exposing the preset area; and stripping the superconducting layer mask 31 after plating the superconducting material through the superconducting layer mask 31, to form a superconducting layer 32 in the preset area. The photoresist can be ultraviolet photoresist, and the corresponding photoetching process can be ultraviolet lithography.

In other words, in this step, a superconducting layer mask 31 may be first formed on the surface of the separation layer 2 by a photolithographic process, and the superconducting layer mask may expose the preset area to shield other areas of the separation layer 2. Then, a superconducting material is plated on the surface of the separation layer 2 based on the superconducting layer mask 31, wherein the surface of the separation layer 2 in the preset area is plated with the superconducting material because the superconducting layer mask 31 is not shielded. The surface of the separation layer 2 beyond the preset area is plated on the surface of the superconducting layer mask 31 due to the shielding of the superconducting layer mask 31. Finally, by stripping the superconducting layer mask 31, only the superconducting material disposed in the preset area remains on the surface of the separation layer 2, forming the superconducting layer 32.

In the process of arranging the superconducting layer mask 31, an electron beam photoresist layer with a thickness of about 2 μm may be uniformly coated on the surface of the first substrate 1 and baked; afterwards, a layer of LOR (Lift-Off Resist) (negative photoresist) is uniformly applied on the surface of the above sample first, and then a layer of AZ4620 ultraviolet photoresist with a thickness of about 15 μm is uniformly applied for ultraviolet photolithography development, defining the bridge pier and bridge surface areas, and then the sample is subjected to full ultraviolet exposure without development to form a superconducting layer mask 31. Finally, a layer of In is evaporated on the bridge pier and bridge surface areas on the surface of the above sample, which has a thickness of about 5 μm, and then immersed in a developer for development. The ultraviolet photoresist is removed by cleaning, and In of the bridge pier and bridge surface areas is retained, forming a superconducting layer 32. The photoresist model mentioned in this step can be replaced with other models as long as the same purpose can be achieved. At the same time, the specific thickness of the process value mentioned in this step is only one of the present cases, and can be other values according to the actual design, as long as the purpose can be achieved.
S203: shielding an area corresponding to the bridge pier in the superconducting layer through a first mask, and exposing an area corresponding to the bridge surface in the superconducting layer.

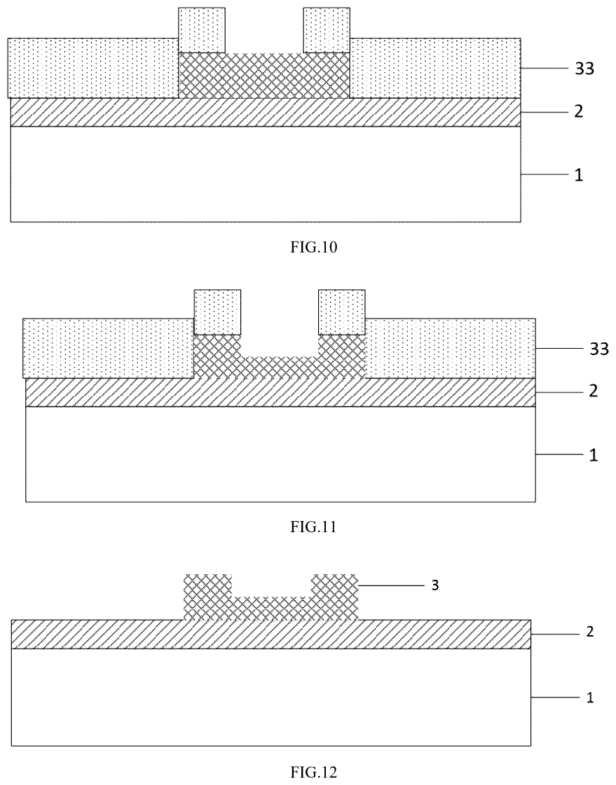

Referring to FIG. 10, as the air bridge 3 needs to be provided on the basis of the superconducting layer 32 in the subsequent steps, the superconducting layer 32 is specifically divided into an area corresponding to the bridge surface and an area corresponding to the bridge pier. In this step, a first mask 33 is further disposed on the surface of the sample on which the superconducting layer 32 is disposed, and then an area corresponding to the bridge pier in the superconducting layer 32 is shielded through a first mask 33, and an area corresponding to the bridge surface in the superconducting layer 32 is exposed, for subsequent etching of the bridge surface area.

Specifically, this step may specifically include arranging a photoresist on the surface of the superconducting layer 32, and photoetching in an area corresponding to the bridge surface to form the first mask 33.

The photoresist can be ultraviolet photoresist, and the corresponding photoetching process can be ultraviolet lithography. That is, in this step, a photoresist is first coated on the surface of the sample provided with the superconducting layer 32, and then the photoresist is etched based on a photolithography process to remove the photoresist corresponding to the bridge surface area to form a first mask 33 for shielding the bridge pier area and exposing the bridge surface area.

Specifically, the process of arranging the first mask 33 may specifically include performing ultraviolet lithography and development on the surface of the sample, defining the bridge surface area, and then performing full UV exposure on the sample to form the first mask 33.
S204: etching an area corresponding to the bridge surface in the superconducting layer through the first mask to form the air bridge.

In this step, the superconducting layer 32 is etched through the first mask 33 to thin the superconducting layer 32 corresponding to the bridge surface area, thereby forming the bridge surface structure and the bridge pier structure in one step, i.e., synchronously forming the one-piece air bridge 3.

Referring to FIG. 11 and FIG. 12, the above process of etching the superconducting layer 32 may specifically utilize an etching process to etch In having a thickness of about 3 μm in the bridge surface area. Finally, after the etching is finished, it is usually necessary to put the above sample into a developer for development to remove the ultraviolet photoresist and then cleaned, and after all the ultraviolet photoresist is removed, the oxygen plasma (plasma) is used for cleaning to remove the residual photoresist, ensuring that no ultraviolet photoresist remains. The etching process for etching the bridge surface area may be a dry etching process or a wet etching process, which is not specifically limited herein.
S205: aligning the first substrate and the second substrate with each other.

Before this step, it is usually necessary to remove the oxide layer on the surface of the superconducting layer 32 by cleaning the first substrate 1 and the second substrate 4, which have been prepared with the structure, with ion milling. The specific content of this step has been described in detail in S103 in the above embodiment of the present disclosure, and will not be described in detail herein.
S206: electrically connecting the air bridge and the circuit device which are aligned with each other.
S207: separating the first substrate and the air bridge from each other through the separation layer after the air bridge and the circuit device are electrically connected with each other, such that the superconducting quantum chip is manufactured.

The specific contents of S206 to S207 have been described in detail in S104 to S105 of the embodiment of the present disclosure, and will not be described in detail herein.

In the superconducting quantum chip preparation method provided by the embodiments of the present disclosure, an air bridge 3 is separately arranged on the surface of the first substrate 1, and then the air bridge 3 is directly flip-chip welded to the surface of the second substrate 4 through a flip-chip welding process to be connected with the circuit device 5, so that the preparation of the air bridge 3 and the preparation of other circuit devices are separated from each other without interfering with each other. Finally, it is only necessary to connect the air bridge 3 and the circuit device 5 to each other by flip-chip bonding equipment, avoiding the interference caused by successively preparing the air bridge 3 and the circuit device 5 on the surface of the substrate, and avoiding the negative impact caused by assembling the air bridge 3. The air bridge 3 in the embodiment of the present disclosure is independently designed, prepared and assembled, and can be independently prepared without being influenced by the preparation progress of other circuits. In the embodiment of the present disclosure, the bridge hole of the air bridge 3 is formed by etching rather than by stripping or arranging a sacrificial layer.

The specific contents of a superconducting quantum chip preparation method provided by the present disclosure will be described in detail in the following embodiments of the present disclosure.

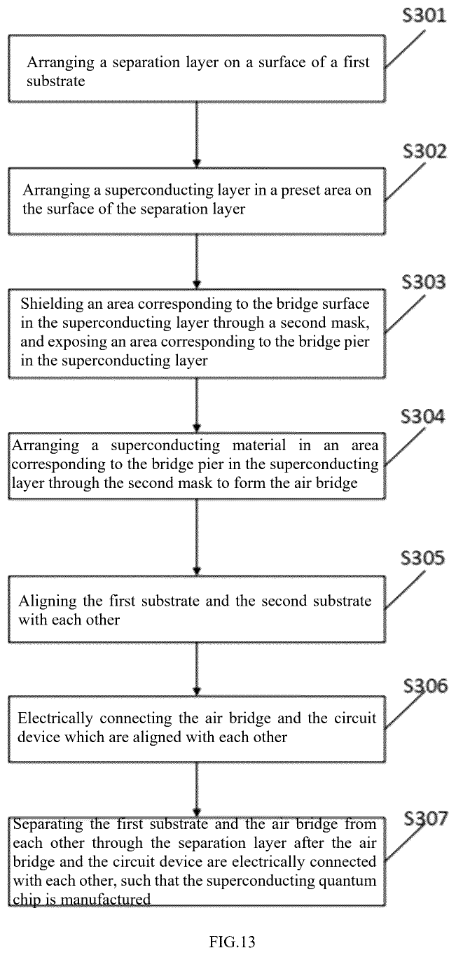

With reference to FIGS. 13 to 16, FIGS. 13 to 16 are process flow diagrams of a further specific superconducting quantum chip preparation method according to an embodiment of the present disclosure.

Referring to FIG. 13, in an embodiment of the present disclosure, a superconducting quantum chip preparation method comprises:
S301: arranging a separation layer on a surface of a first substrate.

This step is basically the same as S101 in the above embodiment of the present disclosure. Please refer to the above embodiment of the present disclosure for details, and the detailed description will not be repeated herein.
S302: arranging a superconducting layer in a preset area on the surface of the separation layer.

This step is basically the same as S202 in the above embodiment of the present disclosure. Please refer to the above embodiment of the present disclosure for details, and the detailed description will not be repeated herein. Specifically, the thickness of the superconducting layer 32 provided in this step is relatively thin with respect to the previous embodiment of the present disclosure, and is generally about 2 μm.

S303: shielding an area corresponding to the bridge surface in the superconducting layer through a second mask, and exposing an area corresponding to the bridge pier in the superconducting layer.

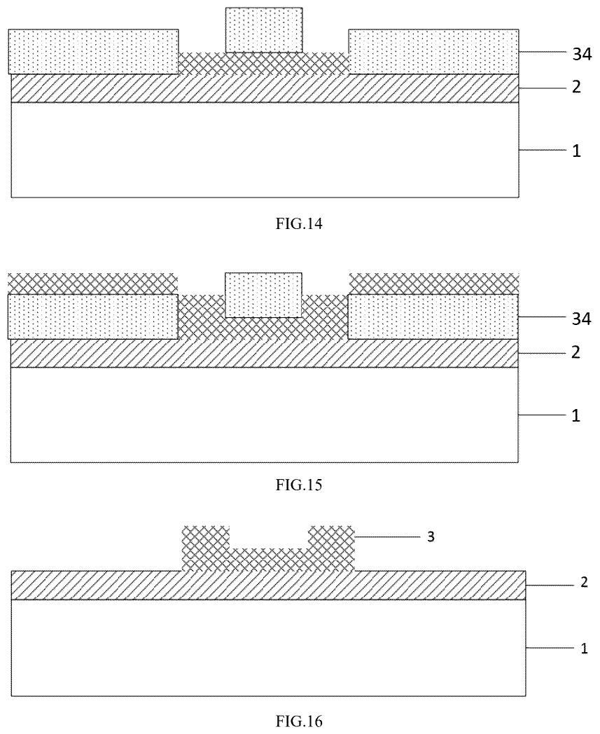

Referring to FIG. 14, as the air bridge 3 needs to be provided on the basis of the superconducting layer 32 in the subsequent steps, the superconducting layer 32 is specifically divided into an area corresponding to the bridge surface and an area corresponding to the bridge pier. In this step, a second mask 34 is further disposed on the surface of the sample on which the superconducting layer 32 is disposed, and then an area corresponding to the bridge surface in the superconducting layer 32 is shielded through a second mask 34, and an area corresponding to the bridge pier in the superconducting layer 32 is exposed, so as to subsequently arrange a superconducting material in the bridge pier area to form the bridge pier.

Specifically, this step may specifically include arranging a photoresist on the surface of the superconducting layer 32, and photoetching in an area corresponding to the bridge pier to form the second mask 34. The photoresist can be ultraviolet photoresist, and the corresponding photoetching process can be ultraviolet lithography. That is, in this step, a photoresist is first coated on the surface of the sample provided with the superconducting layer 32, and then the photoresist is etched based on a photolithography process to remove the photoresist corresponding to the bridge pier area to form a second mask 34 for shielding the bridge surface area and exposing the bridge pier area.

In the process of arranging the second mask 34, a layer of LOR (Lift-Off Resist) is uniformly applied on the surface of the above sample first, and then a layer of AZ4620 ultraviolet photoresist with a thickness of about 15 μm is uniformly applied for ultraviolet photolithography development, defining the bridge pier area, and then the sample is subjected to full ultraviolet exposure without development to form a second mask 34. The photoresist model mentioned in this step can be replaced with other models as long as the same purpose can be achieved. At the same time, the specific thickness of the process value mentioned in this step is only one of the present cases, and can be other values according to the actual design, as long as the purpose can be achieved.
S304: arranging a superconducting material in an area corresponding to the bridge pier in the superconducting layer through the second mask to form the air bridge.

Before this step, it is generally necessary to clean the exposed superconducting layer 32 to remove the oxide layer from its surface. Specifically, the oxide layer on the surface of the In layer can be removed by ion milling. In this step, it is necessary to first provide the superconducting material to thicken the superconducting layer 32 in the bridge pier area, forming the integrated air bridge 3 including the bridge pier and the bridge surface.

Referring to FIG. 15 and FIG. 16, this step may specifically include: evaporating a superconducting material through the second mask 34 based on an evaporation process; and stripping the second mask 34 to form the air bridge 3. That is, in this step, the superconducting layer 32 in the bridge pier area may be thickened by a deposition process, for example, about 3 μm. When the second mask 34 is stripped, the sample can be put into a developer for development and photoresist removal and then cleaned, so that the second mask 34 can be stripped, and the superconducting material arranged on the surface of the second mask 34 can be removed. After all ultraviolet photoresist is removed, oxygen plasma can be used for cleaning to remove residual photoresist, so as to ensure that no ultraviolet photoresist remains.

The superconducting layer 32 is made of a material of any of indium (In), tantalum (Ta), niobium (Nb), titanium nitride (TiN), and niobium nitride (NbN). Certainly, the specific material of the superconducting layer 32 is not specifically limited herein, depending on the specific situations. It should be noted that the bridge surface may be a plane, a curved surface or other shapes, and is not specifically limited herein.
S305: aligning the first substrate and the second substrate with each other.

Before this step, it is usually necessary to remove the oxide layer on the surface of the superconducting layer 32 by cleaning the first substrate 1 and the second substrate 4, which have been prepared with the structure, with ion milling. The specific content of this step has been described in detail in S103 in the above embodiment of the present disclosure, and will not be described in detail herein.
S306: electrically connecting the air bridge and the circuit device which are aligned with each other.
S307: separating the first substrate and the air bridge from each other through the separation layer after the air bridge and the circuit device are electrically connected with each other, such that the superconducting quantum chip is manufactured.

The specific contents of S306 to S307 have been described in detail in S104 to S105 of the embodiment of the present disclosure, and will not be described in detail herein.

In the superconducting quantum chip preparation method provided by the embodiments of the present disclosure, an air bridge 3 is separately arranged on the surface of the first substrate 1, and then the air bridge 3 is directly flip-chip welded to the surface of the second substrate 4 through a flip-chip welding process to be connected with the circuit device 5, so that the preparation of the air bridge 3 and the preparation of other circuit devices 5 are separated from each other without interfering with each other. Finally, it is only necessary to connect the air bridge 3 and the circuit device 5 to each other by flip-chip bonding equipment, avoiding the interference caused by successively preparing the air bridge 3 and the circuit device 5 on the surface of the substrate, and avoiding the negative impact caused by assembling the air bridge 3. The air bridge 3 in the embodiment of the present disclosure is independently designed, prepared and assembled, and can be independently prepared without being influenced by the preparation progress of other circuits. And its processing and preparation process has no effect on the performance of other circuit devices, and its design and preparation solution can be more flexible, not limited by other circuit devices 5.

The present disclosure also provides a superconducting quantum chip, which is specifically a superconducting quantum chip prepared by the superconducting quantum chip preparation method according to any one of the embodiments of the present disclosure.

The superconducting quantum chip preparation method provided in the above embodiment of the present disclosure can independently prepare the air bridge 3 without being influenced by the preparation progress of other circuits. And its processing and preparation process has no effect on the performance of other circuit devices 5, and its design and preparation solution can be more flexible, not limited by other circuit devices 5. Thus, a superconducting quantum chip in the embodiment of the present disclosure has a lower manufacturing cost. The specific structure and the preparation process of the superconducting quantum chip provided by the present disclosure have been described in detail in the above embodiments of the present disclosure, and will not be described in detail herein.

Each embodiment in the specification is described in a progressive manner, each embodiment focuses on the differences from other embodiments, and the same or similar parts among the embodiments can be referred to each other.

Those skilled in the art may further realize that the units and algorithmic steps of the examples described in conjunction with the embodiments disclosed herein can be implemented in electronic hardware, computer software, or a combination thereof. To clearly illustrate the interchangeability of hardware and software, the components and steps of the examples have been described generally in terms of function in the above description. Whether these functions are performed in hardware or software depends on the particular application and design constraints of the technical solution. Those skilled in the art may use different methods to implement the described functions for each particular application, but such implementations should not be considered as going beyond the scope of the present disclosure.

The steps of the methods or algorithms described in conjunction with the embodiments disclosed herein may be implemented directly with hardware, a software module executed by a processor, or a combination thereof. A software module may be placed in random access memory (RAM), memory, read-only memory (ROM), electrically programmable ROM, electrically erasable programmable ROM, a register, a hard disk, a removable diskette, a CD-ROM, or any other form of storage medium known in the art.

Finally, it should also be noted that relationship terms such as first and second, etc. are used herein only to distinguish one entity or operation from another without necessarily requiring or implying any such actual relationship or order between those entities or operations. Moreover, the terms “comprise”, “include” or any other variation thereof, are intended to cover a non-exclusive inclusion, such that a process, a method, an article, or an apparatus comprising a list of elements includes not only those elements, but also other elements not explicitly listed or may include elements inherent to the process, method, article, or apparatus. Without further limitation, an element defined by the statement of “comprising a . . . ” does not exclude the further presence of additionally identical elements in a process, a method, an article or an apparatus comprising said element.

A superconducting quantum chip preparation method and superconducting quantum chip are described in detail in the present disclosure. Specific examples are used herein to illustrate the principles and embodiments of the present disclosure, and the above description of the examples is merely intended to aid in the understanding of the methods of the present disclosure and the core concepts thereof. It should be noted that those skilled in the art can make several modifications and variations to the present disclosure without departing from the principles of the present disclosure, and these modifications and variations also fall within the protection scope of the claims of the present disclosure.

What is claimed is:

1. A superconducting quantum chip preparation method, comprising:
arranging a separation layer on a surface of a first substrate;
arranging an air bridge on a surface of the separation layer; a bridge surface of the air bridge is attached to the separation layer, and a bridge pier of the air bridge extends from the separation layer to the direction opposite to one side of the first substrate;
aligning the first substrate and the second substrate with each other; one side of the first substrate facing the second substrate is provided with the air bridge, and one side of the second substrate facing the first substrate is provided with a circuit device;
electrically connecting the air bridge and the circuit device which are aligned with each other; and
separating the first substrate and the air bridge from each other through the separation layer after the air bridge and the circuit device are electrically connected with each other, such that the superconducting quantum chip is manufactured.

2. The method of claim 1, wherein electrically connecting the air bridge and the circuit device which are aligned with each other comprises:
welding the air bridge and the circuit device which are aligned with each other based on a flip-chip bonding equipment.

3. The method of claim 1, wherein arranging an air bridge on a surface of the separation layer comprises:
arranging a superconducting layer in a preset area on the surface of the separation layer;
shielding an area corresponding to the bridge pier in the superconducting layer through a first mask, and exposing an area corresponding to the bridge surface in the superconducting layer; and
etching an area corresponding to the bridge surface in the superconducting layer through the first mask to form the air bridge.

4. The method of claim 3, wherein shielding an area corresponding to the bridge pier in the superconducting layer through a first mask, and exposing an area corresponding to the bridge surface in the superconducting layer comprises:
arranging a photoresist on the surface of the superconducting layer, and photoetching in an area corresponding to the bridge surface to form the first mask.

5. The method of claim 4, wherein arranging a superconducting layer in a preset area on the surface of the separation layer comprises:
arranging a photoresist on the surface of the separation layer, and photoetching in a corresponding preset area to form a superconducting layer mask exposing the preset area; and
stripping the superconducting layer mask after plating the superconducting material through the superconducting layer mask, to form a superconducting layer in the preset area.

6. The method of claim 1, wherein arranging an air bridge on a surface of the separation layer comprises:
arranging a superconducting layer in a preset area on the surface of the separation layer;
shielding an area corresponding to the bridge surface in the superconducting layer through a second mask, and exposing an area corresponding to the bridge pier in the superconducting layer; and
arranging a superconducting material in an area corresponding to the bridge pier in the superconducting layer through the second mask to form the air bridge.

7. The method of claim 6, wherein shielding an area corresponding to the bridge surface in the superconducting layer through a second mask, and exposing an area corresponding to the bridge pier in the superconducting layer comprises:
arranging a photoresist on the surface of the superconducting layer, and photoetching in an area corresponding to the bridge pier to form the second mask.

8. The method of claim 7, wherein arranging a superconducting material in an area corresponding to the bridge pier in the superconducting layer through the second mask to form the air bridge comprises:
evaporating a superconducting material through the second mask based on an evaporation process; and
stripping the second mask to form the air bridge.

9. The method of claim 1, wherein the separation layer is an electron beam photoresist layer;
the step of separating the first substrate and the air bridge from each other through the separation layer comprises:
immersing the electrically connected sample into a dissolving solution to dissolve the separation layer to separate the first substrate and the air bridge.

10. A superconducting quantum chip comprising a superconducting quantum chip prepared by a superconducting quantum chip preparation method of claim 1.
